(19) United States
(12) Patent Application Publication
(10) Pub. No.: US 2024/0074022 A1
(43) Pub. Date: Feb. 29, 2024

(54) POSITION DETECTION APPARATUS, POSITION DETECTION METHOD AND NON-TRANSITORY COMPUTER-READABLE MEDIUM

(71) Applicant: Lasertec Corporation, Yokohama (JP)

(72) Inventors: Tsunehito KOHYAMA, Yokohama-shi (JP); Keitaro HAYASHIDA, Yokohama-shi (JP); Masayasu NISHIZAWA, Yokohama-shi (JP)

(21) Appl. No.: 18/458,913

(22) Filed: Aug. 30, 2023

(30) Foreign Application Priority Data
Aug. 31, 2022 (JP) 2022-137477

(51) Int. Cl. H05G 2/00; G01B 11/14

(52) U.S. Cl. CPC H05G 2/008; G01B 11/14

(57) ABSTRACT

Provided are a position detection apparatus and a position detection method capable of detecting a position of plasma on a target. The position detection apparatus according to the present disclosure includes: a visible light optical system configured to condense visible light generated together with EUV light from plasma generated by condensing laser light onto a target with a condensing lens; a position detection sensor configured to detect the visible light condensed by the visible light optical system; and a position detection processing unit configured to detect a change in a position of the plasma on the target, from a change in a spot of the visible light detected by the position detection sensor.

### CROSS REFERENCE TO RELATED APPLICATION

This application is based upon and claims the benefit of priority from Japanese Patent Application No. 2022-137477, filed on Aug. 31, 2022, the disclosure of which is incorporated herein in its entirety by reference.

### BACKGROUND

The present disclosure relates to a position detection apparatus and a position detection method for plasma generated on a target by irradiating with laser light in an EUV (Extreme Ultra Violet) light source, for example.

In Japanese Unexamined Patent Application Publication Nos. 2021-001924, 2014-086523, and 2011-003887, a light source is disclosed that irradiates a target such as tin (Sn) with IR (Infra Red) laser light to pump the target and emit EUV light from generated plasma. The EUV light extracted from the light source is used in an inspection apparatus, an exposure apparatus, and the like for a semiconductor substrate.

### SUMMARY

When a position of the target changes during irradiation on the target with the IR laser light, an optical axis of the EUV light to be generated changes, and an optical axis of the EUV light extracted toward an apparatus such as the inspection apparatus, the exposure apparatus, or the like also changes. In order to stabilize the optical axis of the EUV light, it is necessary to detect changes in position of the target.

An object of the present disclosure is to solve such problems, and to provide a position detection apparatus and a position detection method capable of detecting a position of plasma on a target.

A position detection apparatus according to the present disclosure includes: a visible light optical system configured to condense visible light generated together with EUV light from plasma generated by condensing laser light onto a target with a condensing lens; a position detection sensor configured to detect the visible light condensed by the visible light optical system; and a position detection processing unit configured to detect a change in a position of the plasma on the target, from a change in a spot of the visible light detected by the position detection sensor.

In the position detection apparatus, the position detection processing unit may calculate, so as to correct an optical axis of an EUV light optical system configured to condense the EUV light, a change in the optical axis of the EUV light optical system, based on the detected change in the position of the plasma.

In the position detection apparatus, the position detection processing unit may detect, from a position of the spot of the visible light detected by the position detection sensor, a change in a position of the plasma in a direction of an optical axis of the condensing lens and a change in a position of the plasma in a direction orthogonal to the optical axis of the condensing lens.

In the position detection apparatus, the position detection processing unit may detect, from a size of the spot of the visible light detected by the position detection sensor, a change in a position of the plasma in a direction of an optical axis of the condensing lens.

In the position detection apparatus, the position detection apparatus may further include a shielding plate arranged between the position detection sensor and the visible light optical system to shield a central portion including the optical axis of the condensing lens in a cross section of the visible light from the position detection sensor, and the position detection processing unit may detect, from a size of the spot of an annular shape detected by the position detection sensor, the change in the position of the plasma in the direction of the optical axis of the condensing lens.

In the position detection apparatus, the position detection processing unit may detect, from a position of the spot of the annular shape detected by the position detection sensor, a change in a position of the plasma in a direction orthogonal to the optical axis of the condensing lens.

In the position detection apparatus, the shielding plate may include a mirror that reflects the central portion, the position detection apparatus may further include another position detection sensor configured to detect the central portion, and the position detection processing unit may detect, from a position of the spot detected by the other position detection sensor, a change in a position of the plasma in a direction orthogonal to the optical axis of the condensing lens.

In the position detection apparatus, the position detection processing unit may calculate, so as to correct an optical axis of the laser light, a change in the optical axis of the laser light, based on the detected change in the position of the plasma.

A position detection method according to the present disclosure includes: a step in which a visible light optical system condenses visible light generated together with EUV light from plasma generated by condensing laser light onto a target with a condensing lens; a step in which a position detection sensor detects the visible light condensed by the visible light optical system; and a step in which a position detection processing unit detects a change in a position of the plasma on the target, from a change in a spot of the visible light detected by the position detection sensor.

In the position detection method, the position detection method may further include a step of calculating, so as to correct an optical axis of an EUV light optical system configured to condense the EUV light, a change in the optical axis of the EUV light optical system, based on the change in the position of the plasma detected by the position detection processing unit.

In the position detection method, the step in which the position detection processing unit detects may include detecting, from a position of the spot of the visible light detected by the position detection sensor, a change in a position of the plasma in a direction of an optical axis of the condensing lens and a change in a position of the plasma in a direction orthogonal to the optical axis of the condensing lens.

In the position detection method, the step in which the position detection processing unit detects may include detecting, from a size of the spot of the visible light detected by the position detection sensor, a change in a position of the plasma in a direction of an optical axis of the condensing lens.

In the position detection method, the position detection method may further include a step in which a shielding plate arranged between the position detection sensor and the visible light optical system shields a central portion including the optical axis of the condensing lens in a cross section of the visible light from the position detection sensor, and the step in which the position detection processing unit detects may include detecting, from a size of the spot of an annular shape detected by the position detection sensor, the change in the position of the plasma in the direction of the optical axis of the condensing lens.

In the position detection method, the step in which the position detection processing unit detects may include detecting, from a position of the spot of the annular shape detected by the position detection sensor, a change in a position of the plasma in a direction orthogonal to the optical axis of the condensing lens.

In the position detection method, the shielding plate may include a mirror that reflects the central portion, the position detection method may further include a step in which another position detection sensor detects the central portion, and the step in which the position detection processing unit detects may include detecting, from a position of the spot detected by the other position detection sensor, a change in a position of the plasma in a direction orthogonal to the optical axis of the condensing lens.

In the position detection method, the position detection method may further include a step of calculating, so as to correct an optical axis of the laser light, a change in the optical axis of the laser light, based on the change in the position of the plasma detected by the position detection processing unit.

According to the present disclosure, it is possible to provide a position detection apparatus and a position detection method capable of detecting a position of plasma on a target.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a cross-sectional view illustrating a light source according to a first embodiment;

FIG. 2 is a perspective view illustrating a container of the light source according to the first embodiment;

FIG. 3 is a configuration diagram illustrating a position detection apparatus according to the first embodiment;

FIG. 4 is a configuration diagram illustrating visible light when a position of plasma on a target changes in a Z-axis direction in the position detection apparatus according to the first embodiment;

FIG. 5 is a diagram illustrating spots of the visible light detected by a position detection sensor before and after the change in position of the plasma on the target in the position detection apparatus according to the first embodiment;

FIG. 6 is a configuration diagram illustrating visible light when the position of the plasma on the target changes in at least one of an X-axis direction and a Y-axis direction in the position detection apparatus according to the first embodiment;

FIG. 7 is a block diagram illustrating a position detection processing unit in the position detection apparatus according to the first embodiment;

FIG. 8 is a flowchart illustrating a position detection method according to the first embodiment;

FIG. 9 is a configuration diagram illustrating a position detection apparatus according to a second embodiment;

FIG. 10 is a configuration diagram illustrating visible light when a position of plasma on a target changes in a Z-axis direction in the position detection apparatus according to the second embodiment;

FIG. 11 is a diagram illustrating spots of the visible light detected by a position detection sensor before and after the change in position of the plasma on the target in the position detection apparatus according to the second embodiment;

FIG. 12 is a configuration diagram illustrating visible light when the position of the plasma on the target changes in at least one of an X-axis direction and a Y-axis direction in the position detection apparatus according to the second embodiment;

FIG. 13 is a configuration diagram illustrating a position detection apparatus according to a third embodiment;

FIG. 14 is a configuration diagram illustrating visible light when a position of plasma on a target changes in a Z-axis direction in the position detection apparatus according to the third embodiment;

FIG. 15 is a diagram illustrating spots of the visible light detected by a position detection sensor before and after the change in position of the plasma on the target in the position detection apparatus according to the third embodiment;

FIG. 16 is a configuration diagram illustrating visible light when the position of the plasma on the target changes in at least one of an X-axis direction and a Y-axis direction in the position detection apparatus according to the third embodiment;

FIG. 17 is a diagram illustrating spots of the visible light detected by the position detection sensor when a shielding plate is provided in the position detection apparatus according to the third embodiment;

FIG. 18 is a diagram illustrating spots of the visible light detected by the position detection sensor when the shielding plate is not provided in the position detection apparatus according to the third embodiment;

FIG. 19 is a configuration diagram illustrating a position detection apparatus according to the fourth embodiment;

FIG. 20 is a configuration diagram illustrating visible light when a position of plasma on a target changes in a Z-axis direction in the position detection apparatus according to the fourth embodiment;

FIG. 21 is a diagram illustrating spots of the visible light detected by a position detection sensor before and after the change in position of the plasma on the target in the position detection apparatus according to the fourth embodiment;

FIG. 22 is a configuration diagram illustrating visible light V1 when the position of the plasma on the target changes in at least one of an X-axis direction and a Y-axis direction in the position detection apparatus according to the fourth embodiment;

FIG. 23 is a configuration diagram illustrating a position detection apparatus according to the fifth embodiment; and

FIG. 24 is a diagram illustrating spots of the visible light V1 detected by position detection sensors before and after the change in position of the plasma on the target due to a change in pointing of laser light in the position detection apparatus according to the fifth embodiment.

### DESCRIPTION OF EMBODIMENTS

A specific configuration of the present embodiment will be described below with reference to the drawings. The following description shows preferred embodiments of the present disclosure, and the scope of the present disclosure is not limited to the following embodiments. In the following description, components denoted by the same reference numerals indicate substantially similar contents.

### First Embodiment

A position detection apparatus according to a first embodiment will be described. The position detection apparatus of the present embodiment detects a position of a target of a light source that generates EUV light. The light source irradiates a target such as tin with laser light including IR light to pump the target and generate EUV light from generated plasma. The light source is, for example, a light source of illumination light that illuminates an inspection target in an inspection apparatus. Further, the light source may be used as a light source of exposure light in an exposure apparatus. As an example of the light source, an example will be described in which a molten metal held in a container is used as a target. The light source is not limited to the example in which the molten metal held in the container is used as a target, and may use a solid metal, a liquid droplet, or the like, which generates plasma by irradiation with laser light, as a target. In the following description, first, an item “<Light Source> will be described below, and then an item “Configuration of Position Detection Apparatus” will be described.

### <Light Source>

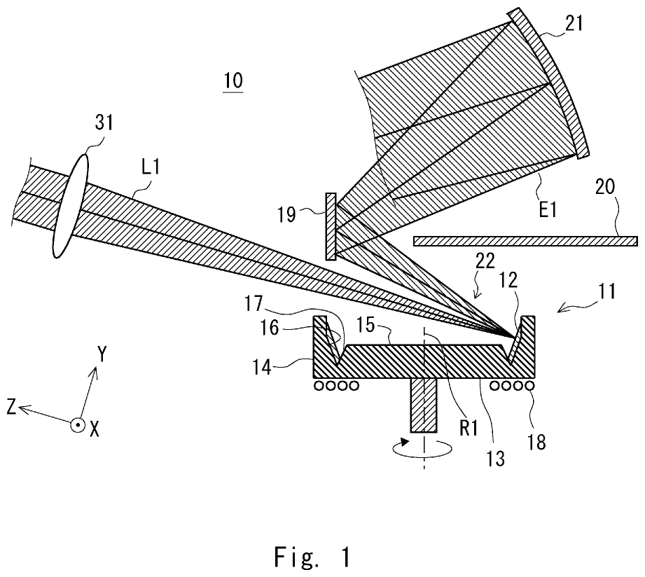

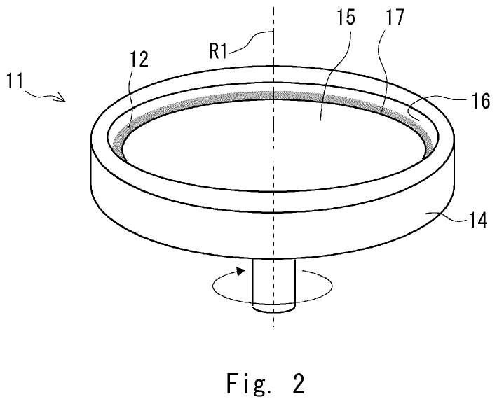

FIG. 1 is a cross-sectional view illustrating a light source according to the first embodiment. FIG. 2 is a perspective view illustrating a container of the light source according to the first embodiment. As shown in FIGS. 1 and 2, a light source 10 includes a container 11. The container 11 is, for example, a crucible in which a metal can be melted. The container 11 holds a target 12 such as a molten metal that generates plasma by irradiation with laser light L1. The target 12 is, for example, a molten metal held in the container 11. The target 12 is not limited to the molten metal held in the container 11, and may be a solid metal, a droplet, or the like as long as it is a substance that generates plasma by irradiation with the laser light L1. The molten metal is, for example, molten tin (Sn) or molten lithium (Li), but is not limited to tin or lithium as long as generating plasma by irradiation with the laser light L1.

The container 11 has a rotation axis R1, and rotates around the rotation axis R1. The container 11 has, for example, a cylindrical shape with one opening closed. The closed portion of the container 11 is referred to as a bottom portion 13. A cylindrical-shaped portion of the container 11 is referred to a cylindrical portion 14. The rotation axis R1 of the container 11 extends in a vertical direction, for example. An inner surface of the bottom portion 13 is referred to as a bottom surface 15. An inner surface of the cylindrical portion 14 is referred to as an inner peripheral surface 16. A groove 17 may be formed in a joining portion between the bottom portion 13 and the cylindrical portion 14.

The inner peripheral surface 16 formed to surround the rotation axis R1 may include a cylindrical portion with a constant distance from the rotation axis R1, or may include a mortar-shaped portion that spreads outward toward a top. For example, the mortar-shaped portion of the inner peripheral surface 16 is connected to the groove 17.

The light source 10 may include a heater 18, a mirror 19, a debris shield 20, and a concave mirror 21 in addition to the container 11. By heating of the heater 18, the target 12 such as a molten metal can be formed in the container 11. The mirror 19 reflects the generated EUV light E1. The EUV light E1 is generated from the plasma generated when the target 12 is irradiated with the laser light L1. The debris shield 20 is arranged in an opening 22 to cover the target 12. The concave mirror 21 reflects the EUV light E1 reflected by the mirror 19, and guides the EUV light E1 to an apparatus such as an inspection apparatus.

The light source 10 may include a laser for pumping that generates the laser light L1, or may introduce the laser light L1 from a laser for pumping installed outside the light source 10 to irradiate the target 12. The laser light L1 is, for example, an IR laser light. The laser light L1 is condensed by a condensing lens 31 and irradiates the target 12.

### <Configuration of Position Detection Apparatus>

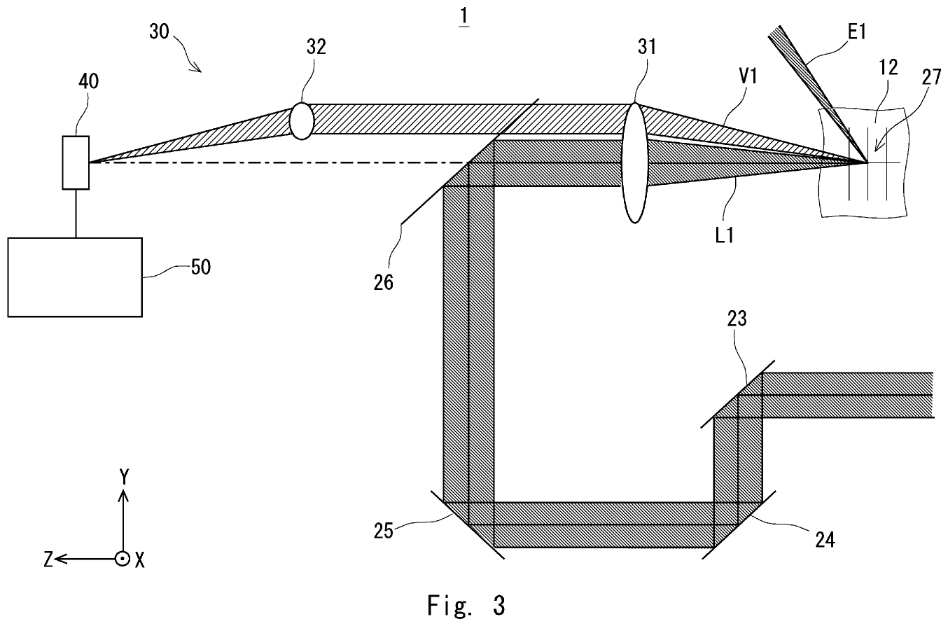

Next, the position detection apparatus of the present embodiment will be described. FIG. 3 is a configuration diagram illustrating the position detection apparatus according to the first embodiment. As shown in FIG. 3, the position detection apparatus 1 includes a visible light optical system 30, a position detection sensor 40, and a position detection processing unit 50.

The laser light L1 is incident on the condensing lens 31 via mirrors 23 to 26, for example. The condensing lens 31 condenses the laser light L1 onto the target 12. The target 12 is pumped by irradiation with the laser light L1. Thus, the target 12 generates plasma 27, and generates EUV light E1. The generated EUV light E1 is extracted to an apparatus such as an inspection apparatus. Visible light V1 is also generated from the plasma 27 together with the EUV light E1. In this way, the visible light V1 is generated together with the EUV light E1 from the plasma 27 generated when the condensing lens 31 condenses the laser light L1 onto the target 12.

Here, for convenience of description of the position detection apparatus 1, an XYZ orthogonal coordinate system is introduced. For example, an optical axis of the condensing lens 31, which condenses the laser light L1 onto the target 12, is defined as a Z-axis direction, and two direction orthogonal to the optical axis of the condensing lens 31 are defined as an X-axis direction and a Y-axis direction respectively.

The visible light optical system 30 condenses the visible light V1 generated together with the EUV light E1. The visible light optical system 30 includes the condensing lens 31 and a lens 32. The visible light optical system 30 may include optical element(s) other than these lenses. The condensing lens 31 is arranged at a position facing the target 12. For example, the condensing lens 31 is arranged in a +Z-axis direction of the target 12. The condensing lens 31 condenses the visible light V1 generated from the target 12. The condensing lens 31 may be used in common with a lens for condensing the laser light L1 and irradiating the target 12 with the condensed laser. In this case, the condensing lens 31 condenses the laser light L1 onto the target 12, and transmits the visible light V1 generated by irradiation of the laser light L1.

The laser light L1 transmits through a central portion including the optical axis of the condensing lens 31 and is condensed onto the target 12. The visible light V1 generated from the plasma 27 on the target 12 transmits through a peripheral portion not including the optical axis of the condensing lens 31. The visible light V1 transmitting through the condensing lens 31 is incident on the lens 32. The lens 32 condenses the visible light V1 onto the position detection sensor 40.

The position detection sensor 40 detects the visible light V1 condensed by the visible light optical system 30. The position detection sensor 40 may detect a spot of the visible light V1 as an image. The position detection sensor 40 outputs information regarding the image of the spot of the detected visible light V1 or the like to the position detection processing unit 50. The position detection processing unit 50 detects a change in position of the plasma 27 on the target 12 from a change in the spot of the visible light V1 detected by the position detection sensor 40.

### <Visible Light V1 Transmits Through Peripheral Portion of Condensing Lens 31. Change in Position in Z-Axis Direction>

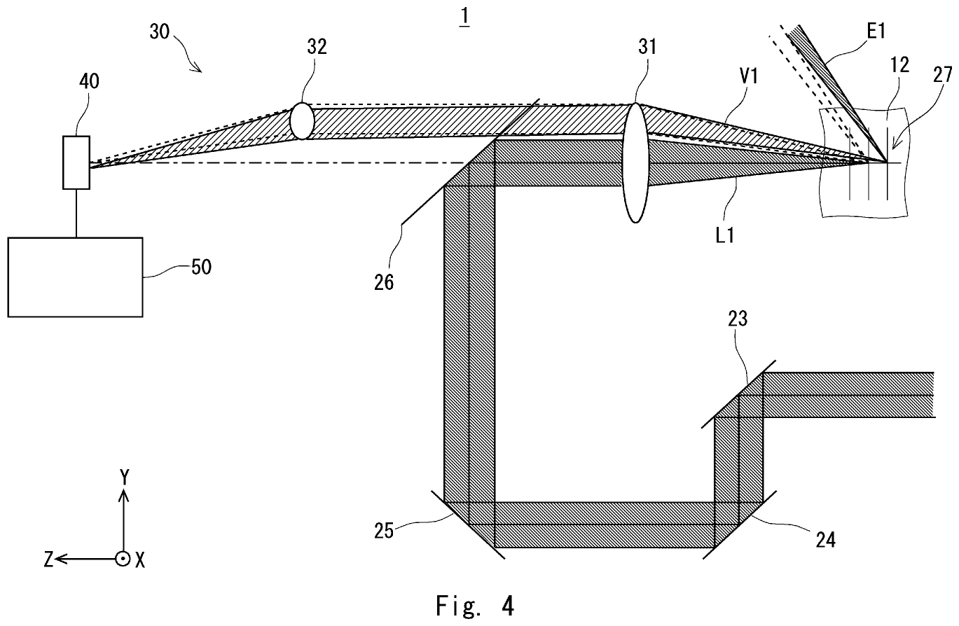

FIG. 4 is a configuration diagram illustrating visible light V1 when the position of the plasma 27 on the target 12 changes in the Z-axis direction in the position detection apparatus 1 according to the first embodiment. As shown in FIG. 4, for example, when the position of the target 12 changes in the Z-axis direction, the position of the plasma 27 generated on the target 12 changes in the Z-axis direction. As a result, the optical axis of the EUV light E1 generated from the plasma 27 changes, and the optical axis of the EUV light E1 in the apparatus such as the inspection apparatus changes. This causes malfunctions in the apparatus such as the inspection apparatus.

When the position of the plasma 27 generated on the target 12 changes, the optical axis of the visible light V1 also changes. The visible light optical system 30 has a configuration for extracting the generated visible light V1 and detecting the change in position of the target 12 using an optical lever method. Specifically, the visible light V1 transmits through the peripheral portion of the condensing lens 31, and is condensed onto the position detection sensor 40 by the lens 32. The position detection sensor 40 detects the visible light V1 as a spot.

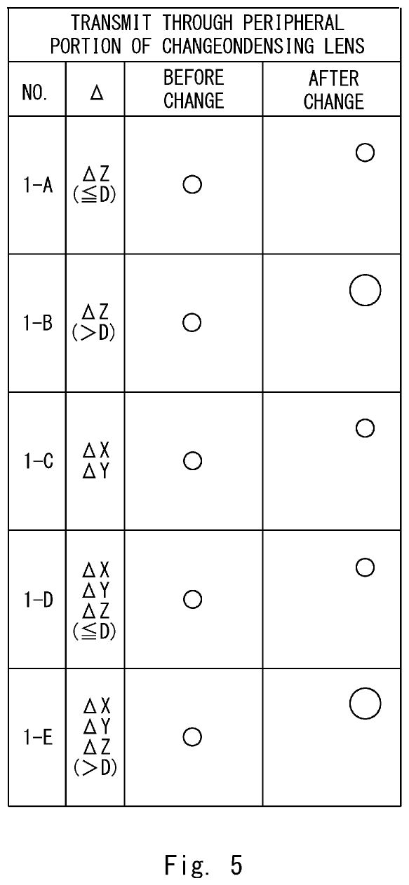

FIG. 5 is a diagram illustrating spots of the visible light V1 detected by the position detection sensor 40 before and after the change in position of the plasma 27 on the target 12 in the position detection apparatus 1 according to the first embodiment. In FIG. 5, NO. 1-A indicates a change ΔZ in position of the plasma 27 in the Z-axis direction, which is equal to or less than a depth of focus D of the condensing lens 31, and NO. 1-B indicates a change ΔZ in position of the plasma 27 in the Z-axis direction, which is larger than the depth of focus D of the condensing lens 31. NO. 1-C indicates a change ΔXΔY in position of the plasma 27 in at least one of the X-axis direction and the Y-axis direction, and NO. 1-D indicates the change ΔZ in position of the plasma 27 in the Z-axis direction, which is equal to or less than a depth of focus D of the condensing lens 31, and the change ΔXΔY in position of the plasma 27 in at least one of the X-axis direction and the Y-axis direction. NO. 1-E indicates the change ΔZ in position of the plasma 27 in the Z-axis direction, which is larger than a depth of focus D of the condensing lens 31, and the change ΔXΔY in position of the plasma 27 in at least one of the X-axis direction and the Y-axis direction.

As indicated by NO. 1-A and NO. 1-B, in the present embodiment, the change ΔZ in position in the Z-axis direction of the plasma 27 on the target 12 is detected by the position detection sensor 40 in different states depending on a relationship with the depth of focus D.

First, as indicated by NO. 1-A in FIG. 5, when the change ΔZ in position of the plasma 27 in the Z-axis direction on the target 12 is equal to or less than the depth of focus D, the change ΔZ in position does not affect the size of the spot of the visible light V1, that is, a bokeh of the spot before and after the change. Therefore, the size of the spot does not change. However, the visible light V1 transmits through the peripheral portion of the condensing lens 31. Therefore, the position detection sensor 40 detects the change ΔZ in position in the Z-axis direction as a change in position of the spot of the visible light V1.

Next, as indicated by NO. 1-B in FIG. 5, when the change ΔZ in position of the plasma 27 in the Z-axis direction on the target 12 is larger than the depth of focus D, the change ΔZ in position affects the size of the spot, that is, a bokeh of the spot before and after the change. Therefore, the size of the spot changes. Further, the visible light V1 transmits through the peripheral portion of the condensing lens 31. Therefore, the position detection sensor 40 detects the change ΔZ in position in the Z-axis direction as a change in position of the spot of the visible light V1.

As described above, when the visible light V1 transmits through the peripheral portion of the condensing lens 31, the position detection sensor 40 detects the change ΔZ in position of the plasma 27 in the optical axis direction of the condensing lens 31 as a change in position of the spot of the visible light V1 regardless of the depth of focus D. Further, when the change ΔZ in position in the Z-axis direction is larger than the depth of focus D, the position detection sensor 40 detects the change ΔZ in position of the plasma 27 in the optical axis direction of the condensing lens 31 as a change in size of the spot of the visible light V1.

<Visible Light Transmits Through Peripheral Portion of Lens. Change in Position in X-Axis and Y-Axis Directions>

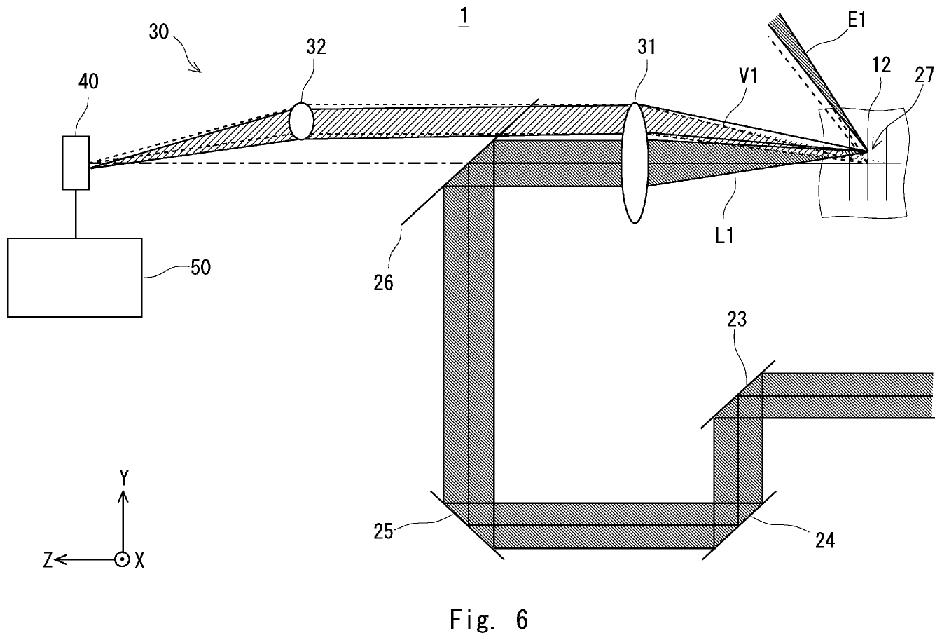

FIG. 6 is a configuration diagram illustrating visible light V1 when the position of the plasma 27 on the target 12 changes in at least one of the X-axis direction and the Y-axis direction in the position detection apparatus 1 according to the first embodiment. As shown in FIG. 6, for example, when pointing of the laser light L1, that is, a condensing position of the laser light L1 changes, the position of the plasma 27 on the target 12 changes in at least one of the X-axis direction and the Y-axis direction. The position detection sensor 40 detects changes ΔXΔY in position of the plasma 27 in the X-axis direction and the Y-axis direction as changes in position of the spot of the visible light V1.

As indicated by NO. 1-C in FIG. 5, the position detection sensor 40 detects the change ΔXΔY in position in at least one of the X-axis direction and the Y-axis direction of the plasma 27 on the target 12, as a change in position of the spot of the visible light V1. It is difficult for the position detection sensor 40 to detect the change ΔXΔY in position as a change in the size of the spot of the visible light V1.

<Visible Light Transmits Through Peripheral Portion of Lens. Change in Position in X-Axis, Y-Axis, and Z-Axis Directions>

As indicated by NO. 1-D and NO. 1-E in FIG. 5, when the change ΔZ in position of the plasma 27 in the Z-axis direction on the target 12 is equal to or less than the depth of focus D, it is difficult for the position detection sensor 40 to detect the change ΔZ in position as the change in the size of the spot. In contrast, when the change ΔZ in position is larger than the depth of focus D, the position detection sensor 40 detects the change ΔZ in position as a change in size of the spot.

On the other hand, as indicated by NO. 1-D and NO. 1-E, the position detection sensor 40 detects the change ΔXΔY in position of the plasma 27 on the target 12, as a change in position of the spot of the visible light V1.

The position detection processing unit 50 detects, from the position of the spot of the visible light V1 detected by the position detection sensor 40, the change in position of the plasma 27 in the optical axis direction of the condensing lens 31 and the change in position of the plasma 27 in a direction orthogonal to the optical axis of the condensing lens 31. Further, the position detection processing unit 50 detects, from the size of the spot of the visible light V1 detected by the position detection sensor 40, the change in position of the plasma 27 in the optical axis direction of the condensing lens 31. The position detection processing unit 50 may calculate, based on the detected change in position of the plasma 27 on the target 12, a change in the optical axis of the EUV light optical system for correcting the optical axis of the EUV light optical system that condenses EUV light. The position detection processing unit 50 may associate the change in position of the plasma 27 with the change in the optical axis of the EUV light optical system in advance, for example. The position detection processing unit 50 may be, for example, an information processing apparatus such as a server apparatus or a personal computer.

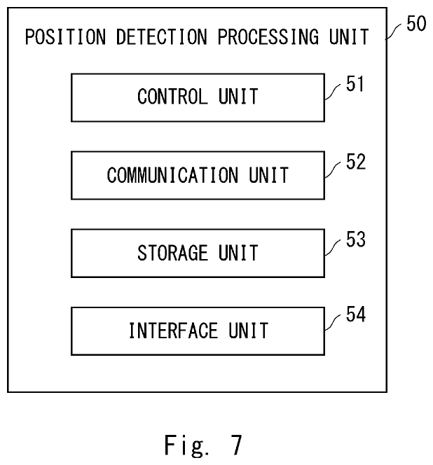

FIG. 7 is a block diagram illustrating the position detection processing unit 50 in the position detection apparatus 1 according to the first embodiment. As shown in FIG. 7, the position detection processing unit 50 includes a control unit 51, a communication unit 52, a storage unit 53, and an interface unit 54. The control unit 51, the communication unit 52, the storage unit 53, and the interface unit 54 functions as control means, communication means, storage means, and interface means, respectively.

The control unit 51 includes processors, for example, a CPU (Central Processing Unit), an MPU (Micro Processing Unit), an ECU (Electronic Control Unit), an FPGA (Field-Programmable Gate Array), and an ASIC (Application Specific Integrated Circuit). The control unit 51 has a function as an arithmetic unit that performs position detection processing, arithmetic processing, and the like. In addition, the control unit 51 controls operations of components for executing functions of the communication unit 52, the storage unit 53, the interface unit 54, and respective apparatuses.

Each of the components of the information processing apparatus can be implemented when a program is executed under control of the control unit 51, for example. More specifically, each of the components can be implemented when a program stored in the storage unit 53 is executed by the control unit 51. Further, each of the components may be implemented when a necessary program is recorded in any nonvolatile recording medium and is installed as necessary. In addition, each of the components may be implemented by any combination of hardware, firmware, and software, without being limited to be implemented with software by a program.

The communication unit 52 performs communication necessary for the position detection processing unit 50 to perform position detection processing. The storage unit 53 is, for example, a ROM (Read Only Memory) or a RAM (Random Access Memory). The storage unit 53 has a function of storing a control program, an arithmetic program, and the like executed by the control unit 51. Further, the storage unit 53 also has a function of temporarily storing image data and the like detected by the position detection sensor 40.

The interface unit 54 is, for example, a user interface. The interface unit 54 is connected to input means such as a keyboard, a touch panel, or a mouse, and output means such as a display or a speaker. The interface unit receives a data input operation from a user (for example, an operator), and outputs information to the user.

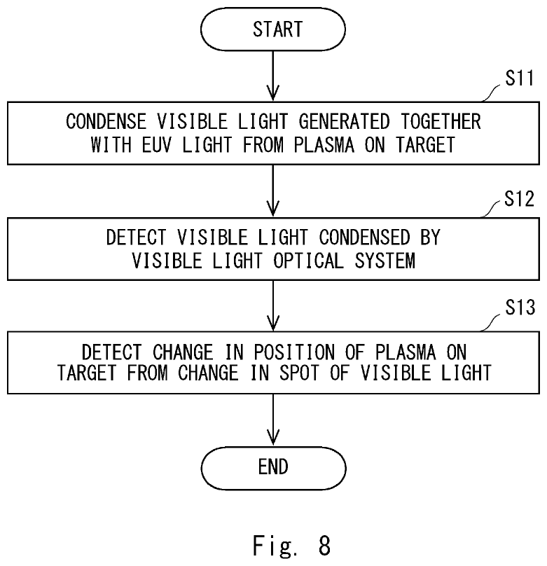

Next, a position detection method of the present embodiment will be described. FIG. 8 is a flowchart illustrating a position detection method according to the first embodiment. As shown in step S11 in FIG. 8, first, the position detection method of the present embodiment condenses the visible light V1 generated together with the EUV light E1 from the plasma 27 on the target 12. Specifically, the laser light L1 is condensed onto the target 12 by the condensing lens 31. The visible light V1 generated together with the EUV light E1 from the plasma 27 generated in this way is condensed by the visible light optical system 30.

Next, as shown in step S12, the position detection sensor 40 detects the visible light V1 condensed by the visible light optical system 30.

Next, as shown in step S13, the position detection processing unit 50 detects the change in position of the plasma 27 on the target 12 from the change in spot of the visible light V1 detected by the position detection sensor 40.

When detecting the change in position of the plasma 27, the position detection processing unit 50 may detect, from the position of the spot of the visible light V1 detected by the position detection sensor 40, the change in position of the plasma 27 in the optical axis direction of the condensing lens 31 and the change in position of the plasma 27 in the direction orthogonal to the optical axis of the condensing lens 31. Further, when detecting the change in position of the plasma 27, the position detection processing unit 50 may detect, from the size of the spot of the visible light V1 detected by the position detection sensor 40, the change in position of the plasma 27 in the optical axis direction of the condensing lens 31.

After the position detection processing unit 50 detects the change in position of the plasma 27, the position detection processing unit 50 may calculate, based on the detected change in position of the plasma 27 on the target 12, the change in the optical axis of the EUV light optical system for correcting the optical axis of the EUV light optical system that condenses EUV light E1.

Next, effects of the present embodiment will be described. In the position detection apparatus 1 of the present embodiment, the visible light V1 generated together with the EUV light E1 from the plasma 27 transmits through the peripheral portion of the condensing lens 31. Therefore, it is possible to detect, from the position of the spot of the visible light V1 detected by the position detection sensor 40, the change ΔZ in position of the plasma 27 in the optical axis direction of the condensing lens 31 and the change ΔXΔY in position of the plasma 27 in the direction orthogonal to the optical axis of the condensing lens 31.

In addition, when the change ΔZ in position of the plasma 27 in the Z-axis direction on the target 12 is larger than the depth of focus D of the conditioning lens 31, it is possible to detect the change ΔZ in position of the plasma 27 in the optical axis direction of the condensing lens 31, from the size of the spot of the visible light V1.

Furthermore, since the changes ΔXΔY and ΔZ in position of the plasma 27 on the target 12 can be detected, it is possible to correct the optical axis of the EUV light E1 in the inspection apparatus or the like using the EUV light E1.

### Second Embodiment

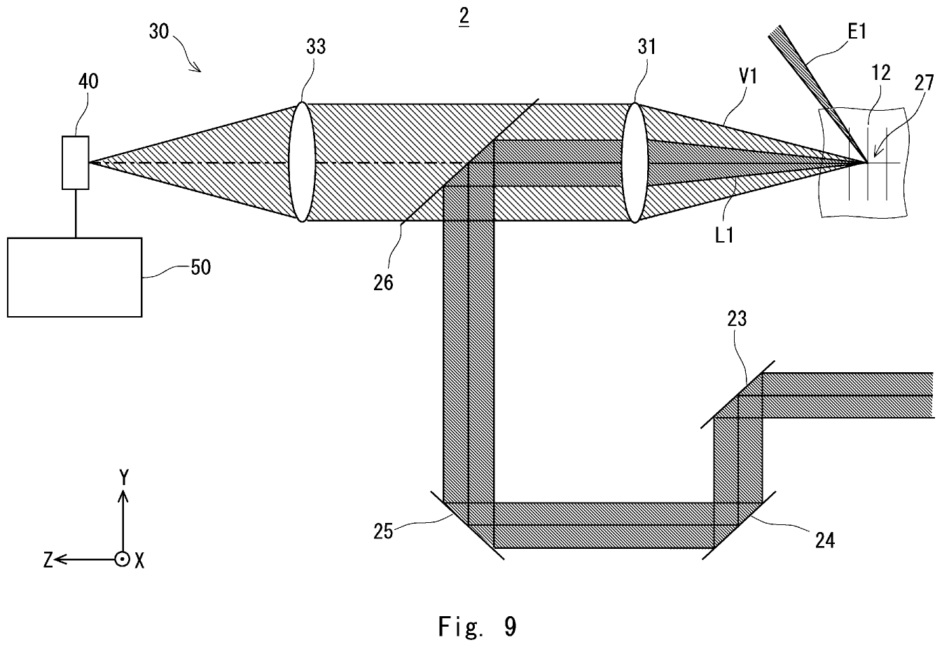

Next, a position detection apparatus according to the second embodiment will be described. In the position detection apparatus of the present embodiment, the visible light V1 transmits through the central portion including the optical axis of the condensing lens 31. FIG. 9 is a configuration diagram illustrating the position detection apparatus according to the second embodiment.

As shown in FIG. 9, a position detection apparatus 2 according to the present embodiment includes a visible light optical system 30, a position detection sensor 40, and a position detection processing unit 50. The visible light optical system 30 includes a condensing lens 31 and a lens 33. The condensing lens 31 and the lens 33 coincide in optical axis with each other. In the present embodiment, the visible light V1 transmits through the central portion including the optical axis of the condensing lens 31. The visible light V1 transmitting through the condensing lens 31 is incident on the lens 33. The visible light V1 transmits through the central portion including the optical axis of the lens 33. The lens 33 condenses the visible light V1 onto the position detection sensor 40.

<Visible Light Transmits Through Central Portion of Lens. Change in Position in Z-Axis Direction>

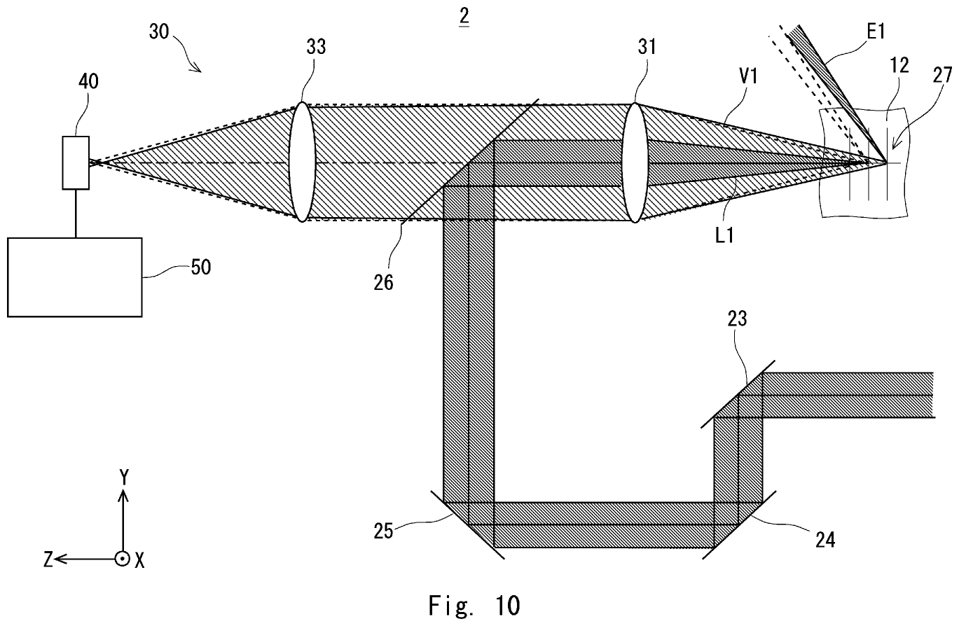

FIG. 10 is a configuration diagram illustrating visible light V1 when a position of the plasma 27 on a target 12 changes in a Z-axis direction in the position detection apparatus 2 according to the second embodiment. As shown in FIG. 10, when the position of the plasma 27 generated on the target 12 changes, the optical axis of the visible light V1 also changes. The visible light V1 transmits through the central portion of the condensing lens 31, and is condensed onto the position detection sensor 40 by the lens 33. The position detection sensor 40 detects the visible light V1 as a spot.

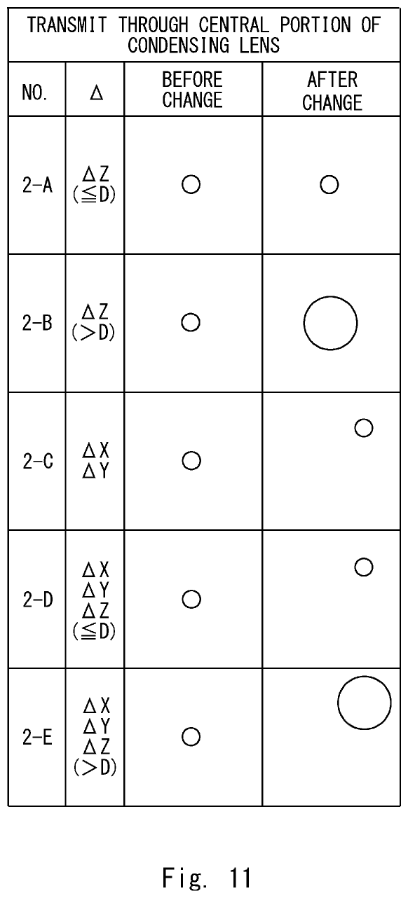

FIG. 11 is a diagram illustrating spots of the visible light V1 detected by the position detection sensor 40 before and after the change in position of the plasma 27 on the target 12 in the position detection apparatus 2 according to the second embodiment. NO. 2-A, NO. 2-B, NO. 2-C, NO. 2-D, and NO. 2-E in FIG. 11 are the same in terms of condition as NO. 1-A, NO. 1-B, NO. 1-C, NO. 1-D, and NO. 1-E in FIG. 5, respectively.

As indicated by NO. 2-A in FIG. 11, when the change ΔZ in position of the plasma 27 in the Z-axis direction on the target 12 is equal to or less than the depth of focus D, the change ΔZ in position does not affect the size of the spot of the visible light V1, that is, a bokeh of the spot before and after the change. Therefore, the size of the spot does not change. Further, the visible light V1 transmits through the central portion of the condensing lens 31. Therefore, the position of the spot detected by the position detection sensor 40 does not change.

Next, as indicated by NO. 2-B in FIG. 11, when the change ΔZ in position of the plasma 27 in the Z-axis direction on the target 12 is larger than the depth of focus D, the change ΔZ in position affects the size of the spot, that is, a bokeh of the spot before and after the change. Therefore, the size of the spot changes. Further, the visible light V1 transmits through the central portion of the condensing lens 31. Therefore, the position of the spot detected by the position detection sensor 40 does not change.

As described above, when the visible light V1 transmits through the central portion of the condensing lens 31, it is difficult for the position detection sensor 40 to detect the change ΔZ in position of the plasma 27 in the optical axis direction of the condensing lens 31 as a change in position of the spot of the visible light V1 regardless of the depth of focus D. On the other hand, when the change ΔZ in position in the Z-axis direction is larger than the depth of focus D, the position detection sensor 40 detects the change ΔZ in position of the plasma 27 in the optical axis direction of the condensing lens 31 as a change in size of the spot of the visible light V1.

<Visible Light Transmits Through Central Portion of Lens. Change in Position in X-Axis and Y-Axis Directions>

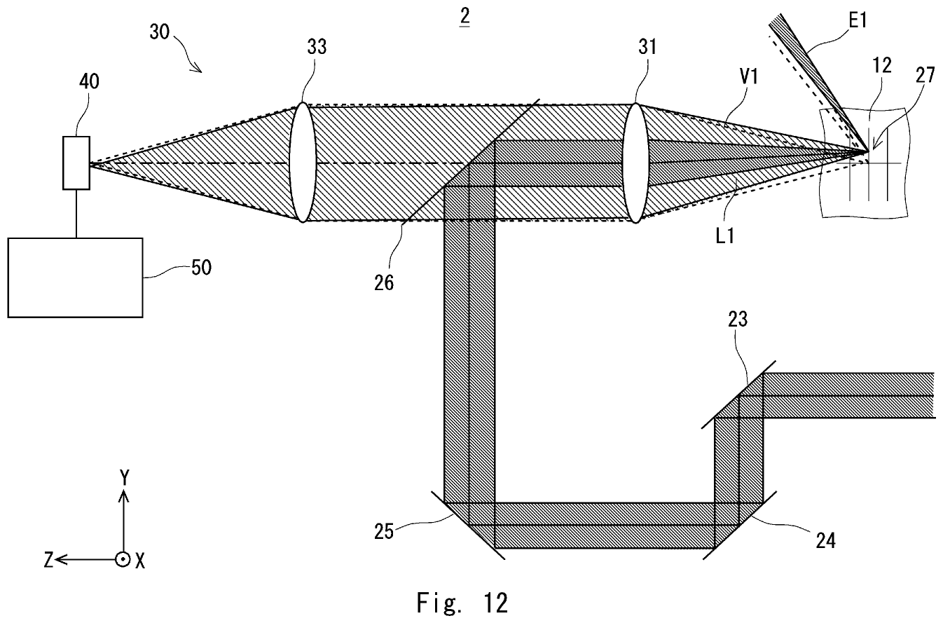

FIG. 12 is a configuration diagram illustrating visible light V1 when the position of the plasma 27 on the target 12 changes in at least one of the X-axis direction and the Y-axis direction in the position detection apparatus 2 according to the second embodiment. As shown in FIG. 12, when pointing of the laser light L1, that is, a condensing position of the laser light L1 changes, the position of the plasma 27 on the target 12 changes in at least one of the X-axis direction and the Y-axis direction. The position detection sensor 40 detects changes ΔXΔY in position of the plasma 27 in the X-axis direction and the Y-axis direction as changes in position of the spot of the visible light V1.

As indicated by NO. 2-C in FIG. 11, the position detection sensor 40 detects the change ΔXΔY in position in at least one of the X-axis direction and the Y-axis direction of the plasma 27 on the target 12, as a change in position of the spot of the visible light V1. It is difficult for the position detection sensor 40 to detect the change ΔXΔY in position as a change in the size of the spot of the visible light V1.

<Visible Light Transmits Through Central Portion of Lens. Change in Position in X-Axis, Y-Axis, and Z-Axis Directions>

As indicated by NO. 2-D and NO. 2-E in FIG. 11, when the change ΔZ in position of the plasma 27 in the Z-axis direction on the target 12 is equal to or less than the depth of focus D, it is difficult for the position detection sensor 40 to detect the change ΔZ in position as the change in the size of the spot. In contrast, when the change ΔZ in position is larger than the depth of focus D, the position detection sensor 40 detects the change ΔZ in position as a change in size of the spot.

On the other hand, as indicated by NO. 2-D and NO. 2-E, the position detection sensor 40 detects the change ΔXΔY in position of the plasma 27 on the target 12, as a change in position of the spot of the visible light V1.

The position detection processing unit 50 detects, from the position of the spot of the visible light V1 detected by the position detection sensor 40, the change in position of the plasma 27 in a direction orthogonal to the optical axis of the condensing lens 31. Further, the position detection processing unit 50 detects, from the change in size of the spot of the visible light V1 detected by the position detection sensor 40, the change in position of the plasma 27 in the optical axis direction of the condensing lens 31.

Next, effects of the present embodiment will be described. The position detection apparatus 2 of the present embodiment allows the visible light V1 to transmit through the central portion including the optical axis of the condensing lens 31. Thus, when the change ΔZ in position is larger than the depth of focus D, the position detection processing unit 50 can detect the change ΔZ in position of the plasma 27 in the optical axis direction of the condensing lens 31 from the change in size of the spot of the visible light V1. In addition, the position detection processing unit 50 can detect the change ΔXΔY in position of the plasma 27 in the direction orthogonal to the optical axis of the condensing lens 31 from the change in position of the spot of the visible light V1. As described above, according to the present embodiment, the change ΔZ in position can be distinguished from the change ΔXΔY in position. Therefore, the position detection apparatus 2 can distinguish between the position of the target 12 in the Z-axis direction and the pointing of the laser light L1. Other configurations and effects are included in the first embodiment.

### Third Embodiment

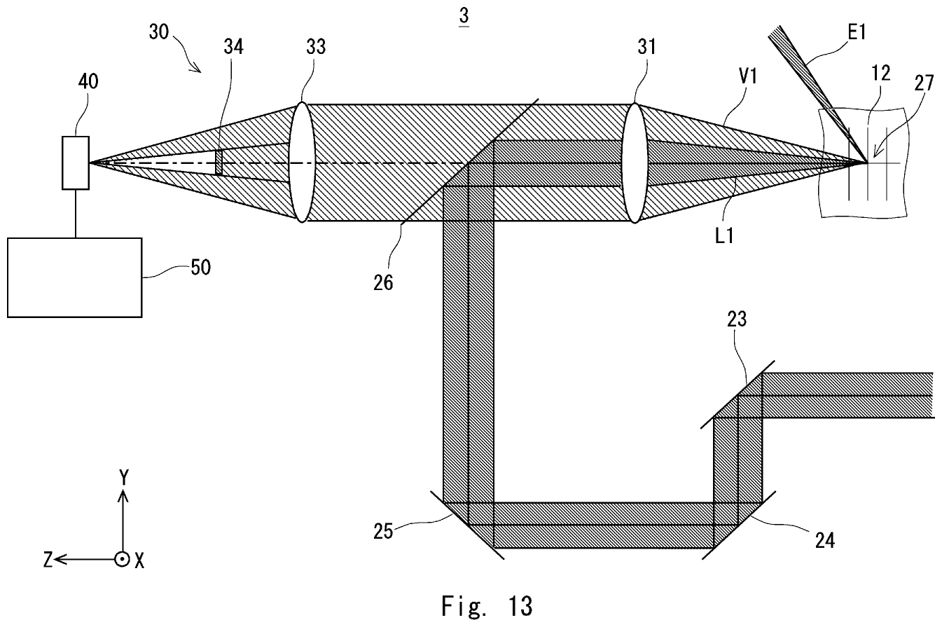

Next, a position detection apparatus according to a third embodiment will be described. The position detection apparatus of the present embodiment includes a shielding plate arranged between a position detection sensor and a visible light optical system. FIG. 13 is a configuration diagram illustrating the position detection apparatus according to the third embodiment.

As shown in FIG. 13, in the present embodiment, a shielding plate 34 of a position detection apparatus 3 is arranged between a position detection sensor 40 and a visible light optical system 30. Specifically, the shielding plate 34 is arranged between the position detection sensor 40 and a lens 33. The shielding plate 34 is arranged on an optical axis of the condensing lens 31 and the lens 33. The shielding plate 34 shields the central portion including the optical axis in a cross section of the visible light V1 from the position detection sensor 40.

The visible light V1 transmits through the central portion including the optical axis of the condensing lens 31. The visible light V1 transmitting through the condensing lens 31 is incident on the lens 33. The visible light V1 transmits through the central portion including the optical axis of the lens 33. The lens 33 condenses the visible light V1 onto the position detection sensor 40. At this time, the shielding plate 34 shields the central portion including the optical axis in the cross section of the visible light V1. Therefore, the peripheral portion other than the central portion of the visible light V1 transmitting through the lens 33 is condensed onto the position detection sensor 40.

<Visible Light Transmits Through Central Portion of Lens. Change in Position in Z-Axis Direction>

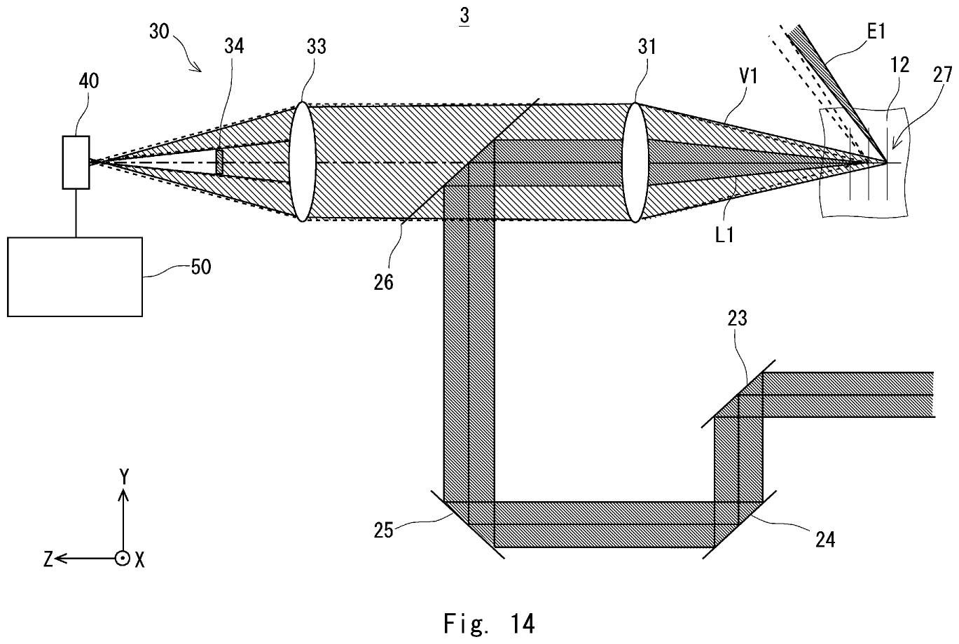

FIG. 14 is a configuration diagram illustrating visible light V1 when a position of the plasma 27 on a target 12 changes in a Z-axis direction in the position detection apparatus 3 according to the third embodiment. As shown in FIG. 14, when the position of the plasma 27 generated on the target 12 changes, the optical axis of the visible light V1 also changes. The visible light V1 transmits through the central portion of the condensing lens 31, and is condensed onto the position detection sensor 40 by the lens 33. At this time, the central portion of the visible light V1 is shielded by the shielding plate 34.

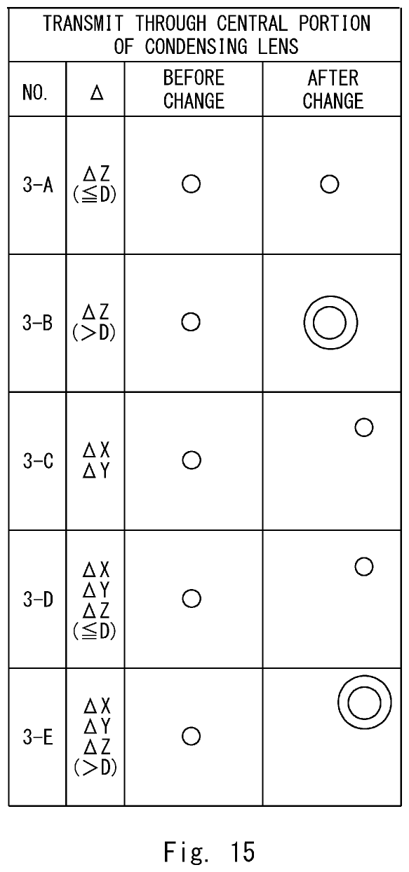

FIG. 15 is a diagram illustrating spots of the visible light V1 detected by the position detection sensor 40 before and after the change in position of the plasma 27 on the target 12 in the position detection apparatus 3 according to the third embodiment. NO. 3-A, NO. 3-B, NO. 3-C, NO. 3-D, and NO. 3-E in FIG. 15 are the same in terms of condition as NO. 1-A, NO. 1-B, NO. 1-C, NO. 1-D, and NO. 1-E in FIG. 5, respectively.

As indicated by NO. 3-A in FIG. 15, when the change ΔZ in position of the plasma 27 in the Z-axis direction on the target 12 is equal to or less than the depth of focus D, the change ΔZ in position does not affect the size of the spot of the visible light V1, that is, a bokeh of the spot before and after the change. Therefore, the size of the spot does not change. Further, the visible light V1 transmits through the central portion of the condensing lens 31. Therefore, the position of the spot detected by the position detection sensor 40 does not change.

Next, as indicated by NO. 3-B in FIG. 15, when the change ΔZ in position of the plasma 27 in the Z-axis direction on the target 12 is larger than the depth of focus D, the change ΔZ in position affects the size of the spot, that is, a bokeh of the spot before and after the change. Therefore, the size of the spot changes. In the present embodiment, the central portion of the visible light V1 is shielded by the shielding plate 34. Therefore, the position detection sensor 40 detects an annular spot. Further, the visible light V1 transmits through the central portion of the condensing lens 31. Therefore, a central position of the annular spot detected by the position detection sensor 40 does not change.

As described above, when the visible light V1 transmits through the central portion of the condensing lens 31, it is difficult for the position detection sensor 40 to detect the change ΔZ in position of the plasma 27 in the optical axis direction of the condensing lens 31 as a change in position of the spot of the visible light V1 regardless of the depth of focus D. On the other hand, when the change ΔZ in position in the Z-axis direction is larger than the depth of focus D, the position detection sensor 40 detects the change ΔZ in position of the plasma 27 in the optical axis direction of the condensing lens 31 as a change in size of the annular spot of the visible light V1.

<Visible Light Transmits Through Central Portion of Lens. Change in Position in X-Axis and Y-Axis Directions>

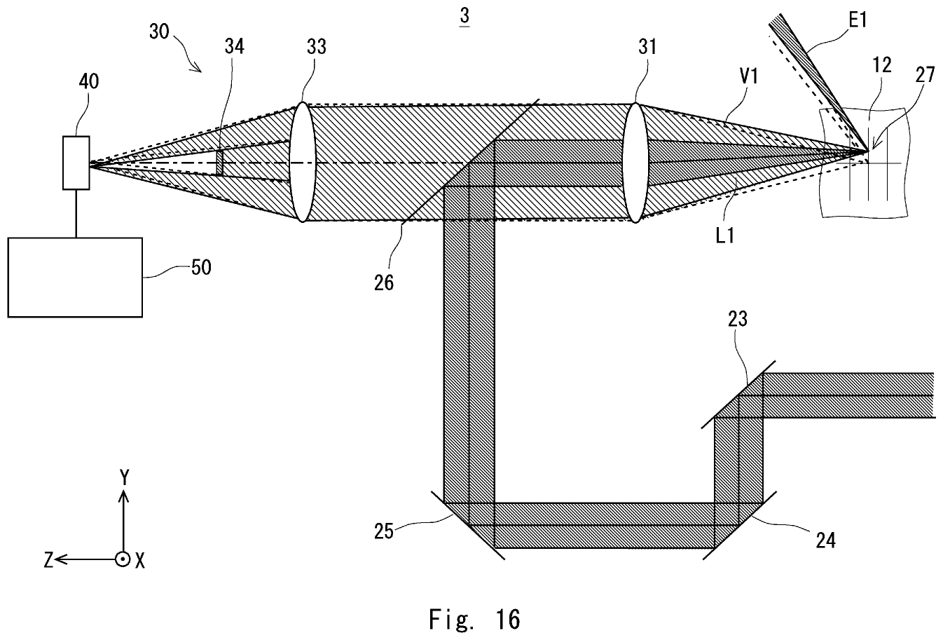

FIG. 16 is a configuration diagram illustrating visible light V1 when the position of the plasma 27 on the target 12 changes in at least one of the X-axis direction and the Y-axis direction in the position detection apparatus 3 according to the third embodiment. As shown in FIG. 16, when pointing of the laser light L1, that is, a condensing position of the laser light L1 changes, the position of the plasma 27 on the target 12 changes in at least one of the X-axis direction and the Y-axis direction. The position detection sensor 40 detects changes ΔXΔY in position of the plasma 27 in the X-axis direction and the Y-axis direction as changes in position of the spot of the visible light V1.

As indicated by NO. 3-C in FIG. 15, the position detection sensor 40 detects the change ΔXΔY in position in at least one of the X-axis direction and the Y-axis direction of the plasma 27 on the target 12, as a change in position of the spot of the visible light V1. It is difficult for the position detection sensor 40 to detect the change ΔXΔY in position as a change in the size of the spot of the visible light V1.

<Visible Light Transmits Through Central Portion of Lens. Change in Position in X-Axis, Y-Axis, and Z-Axis Directions>

As indicated by NO. 3-D and NO. 3-E in FIG. 15, when the change ΔZ in position of the plasma 27 in the Z-axis direction on the target 12 is equal to or less than the depth of focus D, the position detection sensor 40 does not detect the change ΔZ in position as the change in the size of the spot. In contrast, when the change ΔZ in position is larger than the depth of focus D, the position detection sensor 40 detects the change ΔZ in position as a change in size of the annular spot.

On the other hand, as indicated by NO. 3-D and NO. 3-E, the position detection sensor 40 detects the change ΔXΔY in position of the plasma 27 on the target 12, as a change in central position of the annular spot of the visible light V1.

The position detection processing unit 50 detects, from the position of the annular spot of the visible light V1 detected by the position detection sensor 40, the change in position of the plasma 27 in a direction orthogonal to the optical axis of the condensing lens 31. Further, the position detection processing unit 50 detects, from the change in size of the annular spot of the visible light V1 detected by the position detection sensor 40, the change in position of the plasma 27 in the optical axis direction of the condensing lens 31.

Next, effects of the present embodiment will be described. The position detection apparatus 3 of the present embodiment allows the visible light V1 to transmit through the central portion including the optical axis of the condensing lens 31. Then, the central portion of the visible light V1 is shielded by the shielding plate 34. Thus, the position detection processing unit 50 can detect the change ΔZ in position of the plasma 27 in the optical axis direction of the condensing lens 31 from the change in size of the annular spot when the change ΔZ in position is larger than the depth of focus D. By making the spot annular, it is possible to clarify a contour of the spot, and to improve the measurement accuracy of the size of the spot.

In addition, the position detection processing unit 50 can detect the change ΔXΔY in position of the plasma 27 in the direction orthogonal to the optical axis of the condensing lens 31 from the change in the central position of the annular spot. By making the spot annular, it is possible to clarify the central position of the spot from the contour of the spot, and to improve the measurement accuracy of the position of the spot.

As described above, according to the present embodiment, the change ΔZ in position can be distinguished from the change ΔXΔY in position. Therefore, the position detection apparatus 3 can distinguish between the position of the target 12 in the Z-axis direction and the pointing of the laser light L1. Further, it is possible to improve the measurement accuracy of the size and position of the spot.

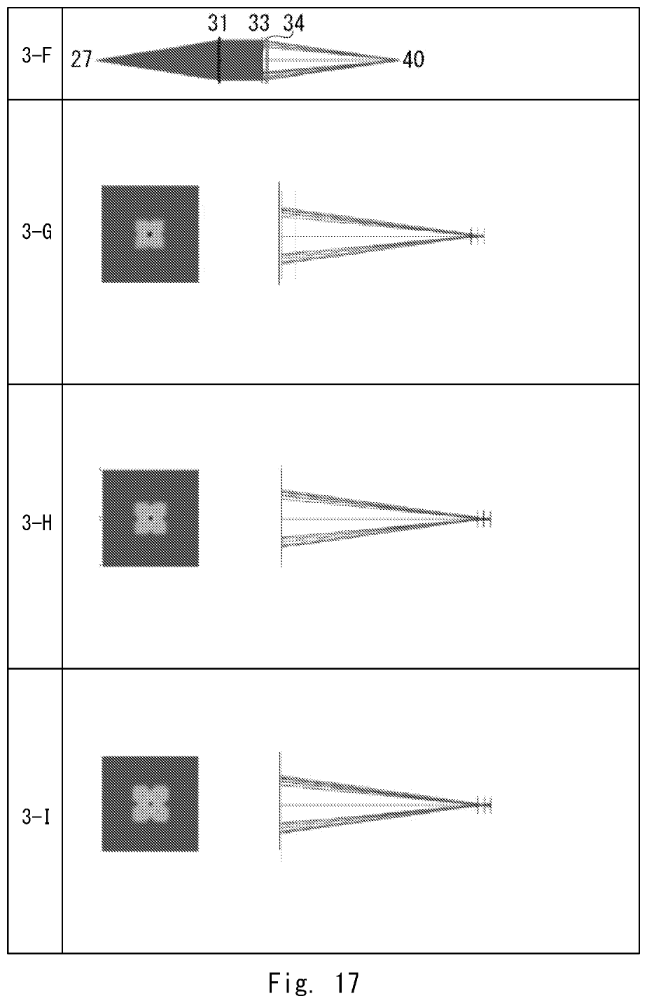

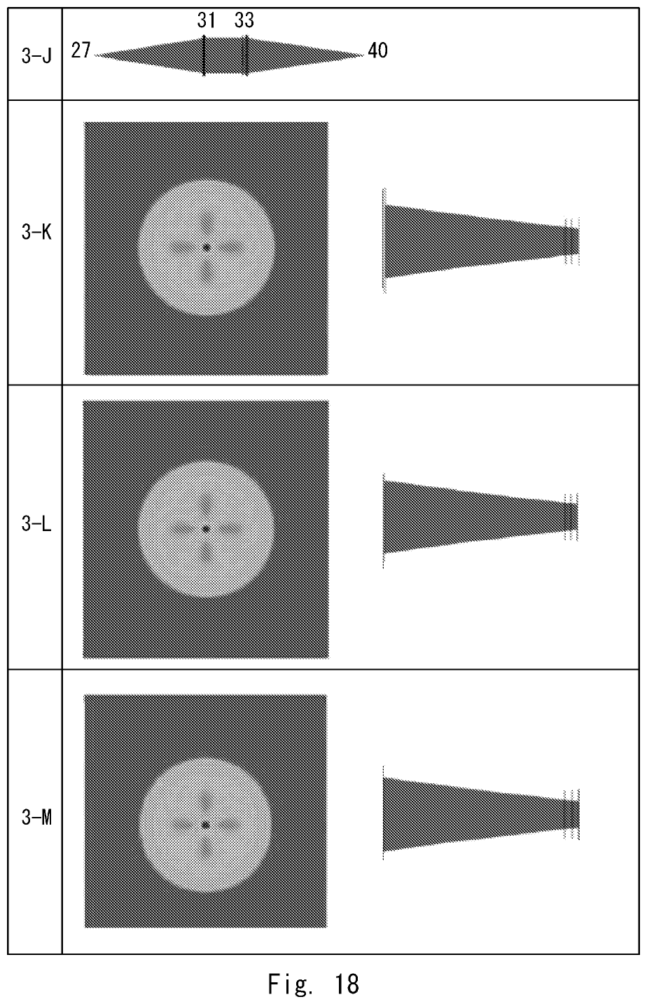

FIG. 17 is a diagram illustrating spots of the visible light detected by the position detection sensor 40 when the shielding plate 34 is provided in the position detection apparatus 3 according to the third embodiment. FIG. 18 is a diagram illustrating spots of the visible light detected by the position detection sensor 40 when the shielding plate 34 is not provided in the position detection apparatus 3 according to the third embodiment.

As indicated by 3-F in FIG. 17, for example, when a radius of the lens 33 is 60 mm and a radius of the shielding plate 34 arranged on the lens 33 is 59 mm, the visible light V1 emitted from the leftmost plasma 27 is incident on the rightmost position detection sensor 40 through the condensing lens 31, the lens 33, and the shielding plate 34.

As indicated by 3-G in FIG. 17, an image with one side of 0.5 mm shows the spot of the visible light V1 detected by the position detection sensor 40 before the position of the plasma 27 is changed. 3-H and 3-I in FIG. 17 indicate spots when the position of the plasma changes +50 μm and +100 μm, respectively, in the Z-axis direction. The greater the change in position of the plasma, the greater the size of the spot.

As indicated by 3-J in FIG. 18, for example, when a radius of the lens 33 is 60 mm and the shielding plate 34 is not arranged on the lens 33, the visible light V1 emitted from the leftmost plasma 27 is incident on the rightmost position detection sensor 40 through the condensing lens 31 and the lens 33.

As indicated by 3-K in FIG. 18, an image with one side of 1.5 mm shows the spot of the visible light V1 detected by the position detection sensor 40 before the position of the plasma 27 is changed. 3-L and 3-M in FIG. 18 indicate spots when the position of the plasma changes +50 μm and +100 μm, respectively, in the Z-axis direction. The greater the change in position of the plasma, the greater the size of the spot.

Comparing FIGS. 17 and 18, the arrangement of the shielding plate 34 can make a depth of focus shallow, improve an NA, and reduce aberrations. Therefore, it is possible to improve the amount of change in position of the plasma 27 that is detectable by the position detection sensor 40. Other configurations and effects are included in the first and second embodiments.

### Fourth Embodiment

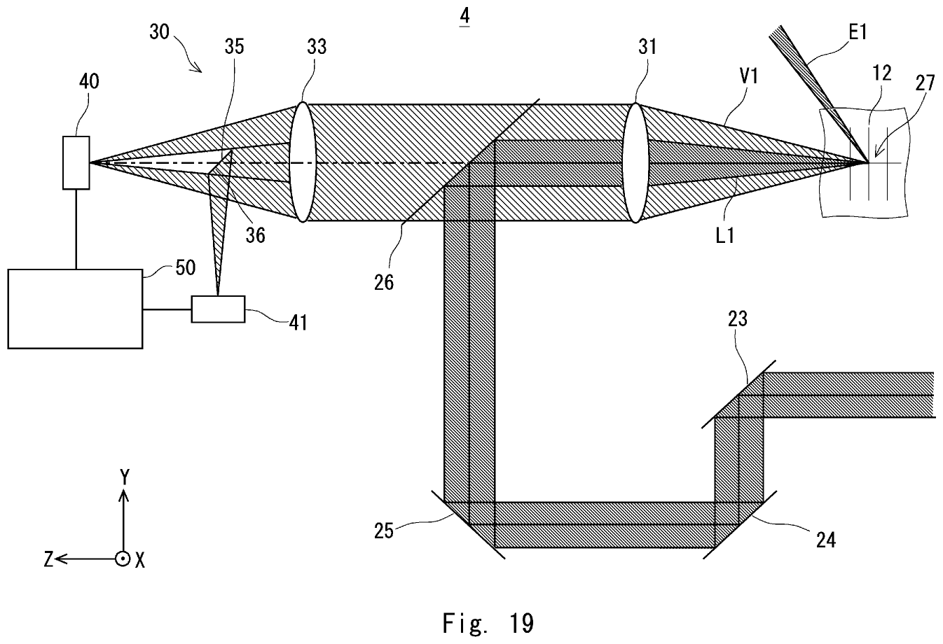

Next, a position detection apparatus according to a fourth embodiment will be described. The position detection apparatus of the present embodiment reflects the central portion of the visible light V1 with a mirror and detects it with another position detection sensor. FIG. 19 is a configuration diagram illustrating the position detection apparatus according to the fourth embodiment.

As shown in FIG. 19, in the present embodiment, a shielding plate 35 of a position detection apparatus 4 includes a mirror 36 that reflects the central portion of the visible light V1. Further, the position detection apparatus 4 includes a position detection sensor 41 different from the position detection sensor 40. The position detection sensor 41 detects the central portion of the visible light V1 reflected by the mirror 36 of the shielding plate 35. The center shielding is performed by the position detection sensor 40, and thus the same effect can be expected as when the center shielding is provided in the third embodiment.

The visible light V1 transmits through the central portion including the optical axis of the condensing lens 31. The visible light V1 transmitting through the condensing lens 31 is incident on the lens 33. The visible light V1 transmits through the central portion including the optical axis of the lens 33. The lens 33 condenses the visible light V1 onto the position detection sensor 40. At this time, the mirror 36 of the shielding plate 35 reflects the central portion including the optical axis in the cross section of the visible light V1. The mirror 36 reflects the central portion of the visible light V1 to the position detection sensor 41. On the other hand, the shielding plate 35 shields the central portion including the optical axis in the cross section of the visible light V1 from the position detection sensor 40. Therefore, the central portion of the visible light V1 transmitting through the lens 33 is condensed onto the position detection sensor 41. The peripheral portion other than the central portion of the visible light V1 transmitting through the lens 33 is condensed onto the position detection sensor 40.

<Visible Light Transmits Through Central Portion of Lens. Change in Position in Z-Axis Direction>

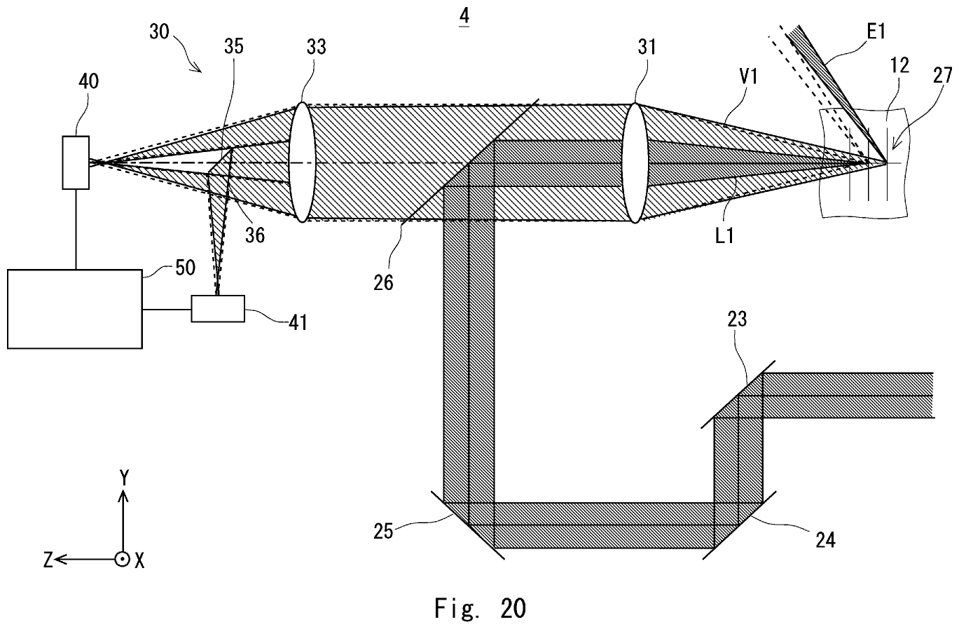

FIG. 20 is a configuration diagram illustrating visible light V1 when a position of the plasma 27 on a target 12 changes in a Z-axis direction in the position detection apparatus 4 according to the fourth embodiment. As shown in FIG. 20, when the position of the plasma 27 generated on the target 12 changes, the optical axis of the visible light V1 also changes. The visible light V1 transmits through the central portion of the condensing lens 31, and is condensed onto the position detection sensor 40 by the lens 33. At this time, the central portion of the visible light V1 is reflected to the position detection sensor 41 by the mirror 36 of the shielding plate 35.

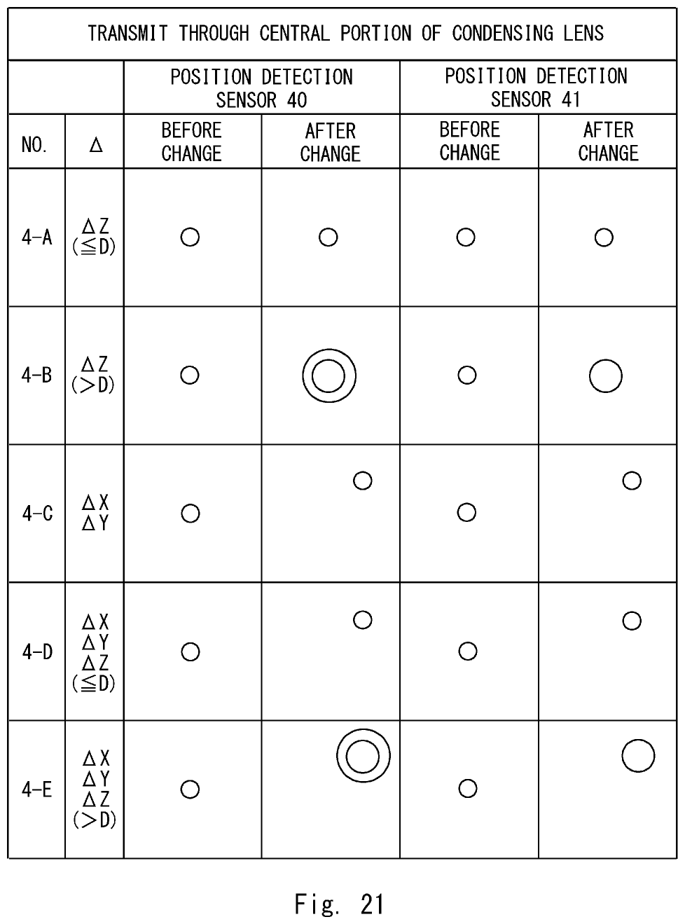

FIG. 21 is a diagram illustrating spots of the visible light V1 detected by the position detection sensors 40 and 41 before and after the change in position of the plasma 27 on the target 12 in the position detection apparatus 4 according to the fourth embodiment. NO. 4-A, NO. 4-B, NO. 4-C, NO. 4-D, and NO. 4-E in FIG. 21 are the same in terms of condition as NO. 1-A, NO. 1-B, NO. 1-C, NO. 1-D, and NO. 1-E in FIG. 5, respectively.

As indicated by NO. 4-A in FIG. 21, when the change ΔZ in position of the plasma 27 in the Z-axis direction on the target 12 is equal to or less than the depth of focus D, the change ΔZ in position does not affect the size of the spot of the visible light V1, that is, a bokeh of the spot before and after the change. Therefore, the size of the spot detected by the position detection sensors 40 and 41 does not change. Further, the visible light V1 transmits through the central portion of the condensing lens 31. Therefore, the position of the spot detected by the position detection sensors 40 and 41 does not change.

Next, as indicated by NO. 4-B in FIG. 21, when the change ΔZ in position of the plasma 27 in the Z-axis direction on the target 12 is larger than the depth of focus D, the change ΔZ in position affects the size of the spot, that is, a bokeh of the spot before and after the change. Therefore, the size of the spot detected by the position detection sensors 40 and 41 changes.

In the present embodiment, the central portion of the visible light V1 is shielded from the position detection sensor 40 by the shielding plate 35. Therefore, the position detection sensor 40 detects an annular spot. Further, the central portion of the visible light V1 is condensed onto the position detection sensor 41 by the mirror 36. Therefore, the position detection sensor 41 detects a spot whose size has changed. The visible light V1 transmits through the central portion of the condensing lens 31. Therefore, central positions of the spots detected by the position detection sensors 40 and 41 do not change.

As described above, when the visible light V1 transmits through the central portion of the condensing lens 31, it is difficult for the position detection sensors 40 and 41 to detect the change ΔZ in position of the plasma 27 in the optical axis direction of the condensing lens 31 as a change in position of the spot of the visible light V1 regardless of the depth of focus D. On the other hand, when the change ΔZ in position in the Z-axis direction is larger than the depth of focus D, the position detection sensors 40 and 41 detect the change ΔZ in position of the plasma 27 in the optical axis direction of the condensing lens 31 as a change in size of the spot of the visible light V1.

<Visible Light Transmits Through Central Portion of Lens. Change in Position in X-Axis and Y-Axis Directions>

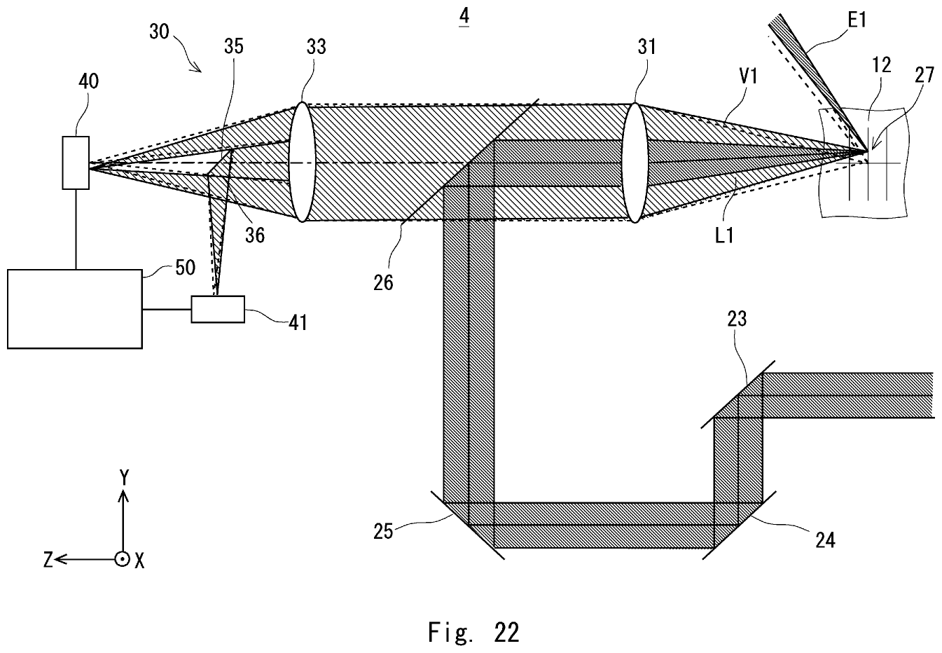

FIG. 22 is a configuration diagram illustrating visible light V1 when the position of the plasma 27 on the target 12 changes in at least one of the X-axis direction and the Y-axis direction in the position detection apparatus 4 according to the fourth embodiment. As shown in FIG. 22, when pointing of the laser light L1, that is, a condensing position of the laser light L1 changes, the position of the plasma 27 on the target 12 changes in at least one of the X-axis direction and the Y-axis direction. The position detection sensors 40 and 41 detect changes ΔXΔY in position of the plasma 27 in the X-axis direction and the Y-axis direction as changes in position of the spot of the visible light V1.

As indicated by NO. 4-C in FIG. 21, the position detection sensors 40 and 41 detect the change ΔXΔY in position in at least one of the X-axis direction and the Y-axis direction of the plasma 27 on the target 12, as a change in position of the spot of the visible light V1. It is difficult for the position detection sensor 40 to detect the change ΔXΔY in position as a change in the size of the spot of the visible light V1.

<Visible Light Transmits Through Central Portion of Lens. Change in Position in X-Axis, Y-Axis, and Z-Axis Directions>

As indicated by NO. 4-D and NO. 4-E in FIG. 21, when the change ΔZ in position of the plasma 27 in the Z-axis direction on the target 12 is equal to or less than the depth of focus D, the position detection sensors 40 and 41 do not detect the change ΔZ in position as the change in the size of the spot. In contrast, when the change ΔZ in position is larger than the depth of focus D, the position detection sensor 40 detects the change ΔZ in position as a change in size of the annular spot. Further, the position detection sensor 41 detects the change ΔZ in position as a change in size of the spot.

On the other hand, as indicated by NO. 4-D and NO. 4-E, the position detection sensor 40 detects the change ΔXΔY in position of the plasma 27 on the target 12, as a change in central position of the annular spot of the visible light V1. Further, the position detection sensor 41 detects the change ΔXΔY in position of the plasma 27 on the target 12, as a change in central position of the spot of the visible light V1.

The position detection processing unit 50 detects, from the position of the annular spot of the visible light V1 detected by the position detection sensor 40 and the position of the spot of the visible light V1 detected by the position detection sensor 41, the change in position of the plasma 27 in a direction orthogonal to the optical axis of the condensing lens 31.

Further, the position detection processing unit 50 detects, from the change in size of the annular spot of the visible light V1 detected by the position detection sensor 40 and the change in size of the spot of the visible light V1 detected by the position detection sensor 41, the change in position of the plasma 27 in the optical axis direction of the condensing lens 31.

Next, effects of the present embodiment will be described. In the position detection apparatus 4 of the present embodiment, the position detection processing unit 50 can detect the change ΔZ in position of the plasma 27 in the optical axis direction of the condensing lens 31 from the change in size of the spot of the visible light V1 detected by the position detection sensors 40 and 41. By making the spot in the position detection sensor 40 annular, it is possible to clarify a contour of the spot, and to improve the measurement accuracy of the size of the spot.

In addition, the position detection processing unit 50 can detect the change ΔXΔY in position of the plasma 27 in the direction orthogonal to the optical axis of the condensing lens 31 from the position of the spot of the visible light V1 detected by the position detection sensors 40 and 41. By making the spot in the position detection sensor 40 annular, it is possible to clarify the central position of the spot from the contour of the spot, and to improve the measurement accuracy of the position of the spot.

According to the present embodiment, the position detection sensor 40 can detect the change ΔZ in position based on the size of the spot, and the position detection sensor 41 can detect the change ΔXΔY in position based on the position of the spot. In this way, the change ΔZ in position and the change ΔXΔY in position can be differentiated and detected by the different position detection sensors 40 and 41, respectively. Therefore, the processing in the position detection processing unit 50 can be efficiently performed in which the detection of the change ΔZ in position from the position detection sensor 40 can be distinguished from the detection of the change ΔXΔY in position from the position detection sensor 41. Other configurations and effects are included in the first to third embodiments.

### Fifth Embodiment

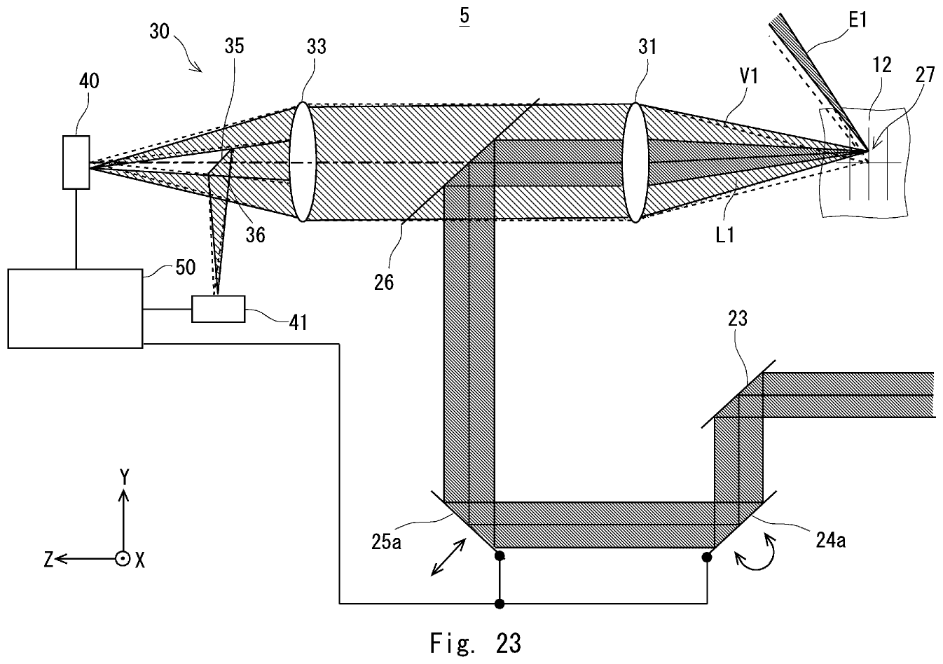

Next, a position detection apparatus according to a fifth embodiment will be described. The position detection apparatus of the present embodiment corrects pointing of the laser light V1 based on the change in position of the spot detected by at least one of the position detection sensors 40 and 41. FIG. 23 is a configuration diagram illustrating the position detection apparatus according to the fifth embodiment. As shown in FIG. 23, a position detection apparatus 5 may include galvanometer mirrors 24a and 25a instead of the mirror 24 and the mirror 25. The galvanometer mirrors 24a and 25a can change a direction of reflection under control of the position detection processing unit 50.

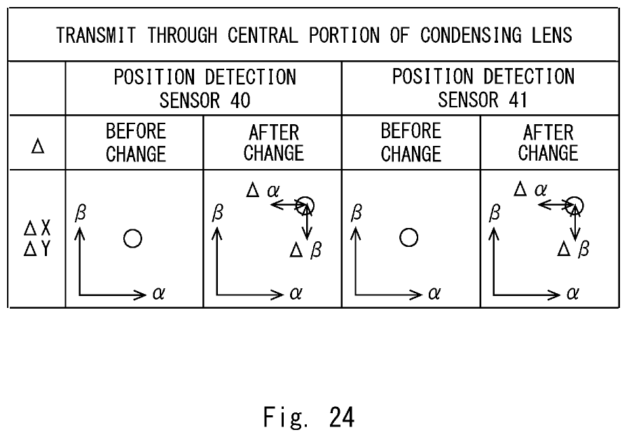

FIG. 24 is a diagram illustrating spots of the visible light V1 detected by the position detection sensors 40 and 41 before and after the change in position of the plasma 27 on the target 12 due to a change in pointing of the laser light L1 in the position detection apparatus 5 according to the fifth embodiment. As shown in FIG. 24, positions of the spots detected by the position detection sensor 41 show a change Δα and a change Δβ in an a direction and a R direction on an image, respectively.

The position detection processing unit adjusts the galvanometer mirrors 24a and 25a based on the change Δα and the change Δβ. For example, a reflection direction of the galvanometer mirror 24a may be adjusted so as to correct the change Δα. A reflection direction of the galvanometer mirror 25a may be adjusted so as to correct the change Δβ.

As described above, according to the position detection apparatus 5 of the present embodiment, the position detection processing unit 50 calculates the change in the optical axis of the laser light L1 so as to correct the pointing of the laser light L1 in addition to calculating the change in the optical axis of the EUV light optical system so as to correct the optical axis of the EUV light optical system on the apparatus such as the inspection apparatus. Specifically, the position detection processing unit 50 calculates the adjustment amount of the galvanometer mirrors 24a and 25a based on the changes Δα and Δβ in position of the spots detected by at least one of the position detection sensors 40 and 41. Then, the position detection processing unit 50 may adjust the reflection directions of the galvanometer mirrors 24a and 25a based on the calculated adjustment amount. For example, the position detection processing unit 50 may perform PID control for adjusting the reflection directions of the galvanometer mirrors 24a and 25a using the changes Δα and Δβ in position of the spots as input values.

According to the present embodiment, the position detection processing unit 50 calculates the change in the optical axis of the laser light L1 for correcting the optical axis of the laser light L1 based on the detected change in position of the plasma 27. Then, the position detection processing unit 50 can correct the pointing of the laser light L1 based on the calculated change in the optical axis of the laser light L1. Therefore, it is possible to improve irradiation conditions of the EUV light in the inspection apparatus and the exposure apparatus. Other configurations and effects are included in the first to fourth embodiments.

Although the embodiments of the present disclosure have been described above, the present disclosure includes appropriate modifications without impairing its object and advantages and is not limited to the above embodiments. Further, the configurations of the first to fifth embodiments may be combined as appropriate.

Furthermore, part or all of the processing of the position detection processing unit 50 described above may be executed by a computer program. The above-described program includes a set of instructions (or software codes) that, when read into a computer, causes the computer to perform one or more of the functions described in the embodiments. The program may be stored in a non-transitory computer-readable medium or in a physical storage medium. By way of example rather than limitation, a computer-readable medium or a physical storage medium may include a random-access memory (RAM), a read-only memory (ROM), a flash memory, a solid-state drive (SSD), or other memory technology, a CD-ROM, a digital versatile disc (DVD), a Blu-ray (registered trademark) disc or other optical disc storages, a magnetic cassette, magnetic tape, and a magnetic disc storage or other magnetic storage devices. The program may be transmitted on a transitory computer-readable medium or a communication medium. By way of example rather than limitation, the transitory computer-readable medium or the communication medium may include electrical, optical, acoustic, or other forms of propagating signals.

The technical scope of the embodiments also includes the following position detection program that causes a computer to execute the position detection method of the present embodiments.

A position detection program that causes a computer to execute: a step in which a visible light optical system condenses visible light generated together with EUV light from plasma generated by condensing laser light onto a target with a condensing lens;
a step in which a position detection sensor detects the visible light condensed by the visible light optical system; and
a step in which a position detection processing unit detects a change in a position of the plasma on the target, from a change in a spot of the visible light detected by the position detection sensor.

The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A position detection apparatus comprising:
a visible light optical system configured to condense visible light generated together with EUV light from plasma generated by condensing laser light onto a target with a condensing lens;
a position detection sensor configured to detect the visible light condensed by the visible light optical system; and
a position detection processing unit configured to detect a change in a position of the plasma on the target, from a change in a spot of the visible light detected by the position detection sensor.

2. The position detection apparatus according to claim 1, wherein the position detection processing unit calculates, so as to correct an optical axis of an EUV light optical system configured to condense the EUV light, a change in the optical axis of the EUV light optical system, based on the detected change in the position of the plasma.

3. The position detection apparatus according to claim 1, wherein the position detection processing unit detects, from a position of the spot of the visible light detected by the position detection sensor, a change in a position of the plasma in a direction of an optical axis of the condensing lens and a change in a position of the plasma in a direction orthogonal to the optical axis of the condensing lens.

4. The position detection apparatus according to claim 1, wherein the position detection processing unit detects, from a size of the spot of the visible light detected by the position detection sensor, a change in a position of the plasma in a direction of an optical axis of the condensing lens.

5. The position detection apparatus according to claim 4, further comprising a shielding plate arranged between the position detection sensor and the visible light optical system to shield a central portion including the optical axis of the condensing lens in a cross section of the visible light from the position detection sensor,
wherein the position detection processing unit detects, from a size of the spot of an annular shape detected by the position detection sensor, the change in the position of the plasma in the direction of the optical axis of the condensing lens.

6. The position detection apparatus according to claim 5, wherein the position detection processing unit detects, from a position of the spot of the annular shape detected by the position detection sensor, a change in a position of the plasma in a direction orthogonal to the optical axis of the condensing lens.

7. The position detection apparatus according to claim 5, wherein
the shielding plate includes a mirror that reflects the central portion,
the position detection apparatus further includes another position detection sensor configured to detect the central portion, and
the position detection processing unit detects, from a position of the spot detected by the other position detection sensor, a change in a position of the plasma in a direction orthogonal to the optical axis of the condensing lens.

8. The position detection apparatus according to claim 1, wherein the position detection processing unit calculates, so as to correct an optical axis of the laser light, a change in the optical axis of the laser light, based on the detected change in the position of the plasma.

9. A position detection method comprising:
a step in which a visible light optical system condenses visible light generated together with EUV light from plasma generated by condensing laser light onto a target with a condensing lens;
a step in which a position detection sensor detects the visible light condensed by the visible light optical system; and
a step in which a position detection processing unit detects a change in a position of the plasma on the target, from a change in a spot of the visible light detected by the position detection sensor.

10. The position detection method according to claim 9, further comprising a step of calculating, so as to correct an optical axis of an EUV light optical system configured to condense the EUV light, a change in the optical axis of the EUV light optical system, based on the change in the position of the plasma detected by the position detection processing unit.

11. The position detection method according to claim 9, wherein the step in which the position detection processing unit detects includes detecting, from a position of the spot of the visible light detected by the position detection sensor, a change in a position of the plasma in a direction of an optical axis of the condensing lens and a change in a position of the plasma in a direction orthogonal to the optical axis of the condensing lens.

12. The position detection method according to claim 9, wherein the step in which the position detection processing unit detects includes detecting, from a size of the spot of the visible light detected by the position detection sensor, a change in a position of the plasma in a direction of an optical axis of the condensing lens.

13. The position detection method according to claim 12, further comprising a step in which a shielding plate arranged between the position detection sensor and the visible light optical system shields a central portion including the optical axis of the condensing lens in a cross section of the visible light from the position detection sensor,
wherein the step in which the position detection processing unit detects includes detecting, from a size of the spot of an annular shape detected by the position detection sensor, the change in the position of the plasma in the direction of the optical axis of the condensing lens.

14. The position detection method according to claim 13, wherein the step in which the position detection processing unit detects includes detecting, from a position of the spot of the annular shape detected by the position detection sensor, a change in a position of the plasma in a direction orthogonal to the optical axis of the condensing lens.

15. The position detection method according to claim 13, wherein
the shielding plate includes a mirror that reflects the central portion,
the position detection method further includes a step in which another position detection sensor detects the central portion, and
the step in which the position detection processing unit detects includes detecting, from a position of the spot detected by the other position detection sensor, a change in a position of the plasma in a direction orthogonal to the optical axis of the condensing lens.

16. The position detection method according to claim 9, further comprising a step of calculating, so as to correct an optical axis of the laser light, a change in the optical axis of the laser light, based on the change in the position of the plasma detected by the position detection processing unit.

17. A non-transitory computer-readable medium storing a position detection program that causes a computer to execute:
a step in which a visible light optical system condenses visible light generated together with EUV light from plasma generated by condensing laser light onto a target with a condensing lens;
a step in which a position detection sensor detects the visible light condensed by the visible light optical system; and
a step in which a position detection processing unit detects a change in a position of the plasma on the target, from a change in a spot of the visible light detected by the position detection sensor.

18. The non-transitory computer-readable medium storing a position detection program according to claim 17, further comprising a step of calculating, so as to correct an optical axis of an EUV light optical system configured to condense the EUV light, a change in the optical axis of the EUV light optical system, based on the change in the position of the plasma detected by the position detection processing unit.

19. The non-transitory computer-readable medium storing a position detection program according to claim 17, wherein the step in which the position detection processing unit detects includes detecting, from a position of the spot of the visible light detected by the position detection sensor, a change in a position of the plasma in a direction of an optical axis of the condensing lens and a change in a position of the plasma in a direction orthogonal to the optical axis of the condensing lens.

20. The non-transitory computer-readable medium storing a position detection program according to claim 17, wherein the step in which the position detection processing unit detects includes detecting, from a size of the spot of the visible light detected by the position detection sensor, a change in a position of the plasma in a direction of an optical axis of the condensing lens.
